(19) United States
(12) Patent Application Publication
(10) Pub. No.: US 2023/0299164 A1
(43) Pub. Date: Sep. 21, 2023

(54) SEMICONDUCTOR STRUCTURE AND METHOD FOR FORMING THE SAME

(71) Applicant: TAIWAN SEMICONDUCTOR MANUFACTURING COMPANY LTD., Hsinchu (TW)

(72) Inventors: JHU-MIN SONG, NANTOU COUNTY (TW); CHIEN-CHIH CHOU, NEW TAIPEI CITY (TW); YU-CHANG JONG, HSINCHU CITY (TW)

(21) Appl. No.: 17/695,839

(22) Filed: Mar. 16, 2022

(51) Int. Cl. H01L 29/423; H01L 27/088; H01L 21/8234

(52) U.S. Cl. CPC H01L 29/4238; H01L 27/088; H01L 29/42364; H01L 21/823456; H01L 21/823462

(57) ABSTRACT

A semiconductor structure includes a first device, a second device, and a plurality of pillars. The first device includes a first dielectric layer, a first high-k dielectric layer over the first dielectric layer, and a first metal gate structure. The second device includes a second dielectric layer, a second high-k dielectric layer over the second dielectric layer, and a second metal gate structure. The first dielectric layer has a first thickness, the second dielectric layer has a second thickness, and the second thickness is less than the first thickness. The pillars are disposed in the first metal gate structure. The pillars are separated from each other by the first metal gate structure.

### BACKGROUND

The electronics industry has experienced an ever-increasing demand for smaller and faster electronic devices that are able to support greater numbers of increasingly complex and sophisticated functions. Accordingly, there is a continuing trend in the semiconductor industry to manufacture low-cost, high-performance, low-power integrated circuits (ICs). Thus far these goals have been achieved in large part by scaling down semiconductor IC dimensions (e.g., minimum feature size) and thereby improving production efficiency and reducing associated costs. However, such downscaling has also introduced increased complexity to the semiconductor manufacturing process.

As technology nodes achieve progressively smaller scales, in some IC designs, researchers have hoped to replace a typical polysilicon gate with a metal gate to improve device performance by decreasing feature sizes. One approach to forming the metal gate is called a “gate-last” approach, sometimes referred to as a replacement polysilicon gate (RPG) approach. In the RPG approach, the metal gate is fabricated last, which allows for a reduced number of subsequent operations.

Further, as the dimensions of a transistor decrease, the thickness of the gate dielectric layer may be reduced to maintain performance with a decreased gate length. In order to reduce gate leakage, a high dielectric constant (high-k or HK) gate dielectric layer is used to provide a performance comparable to that provided by a typical gate oxide used in larger technology nodes. A high-k metal gate (HKMG) approach including the metal gate electrode and the high-k gate dielectric layer is therefore recognized. However, the HKMG approach is a complicated approach, and many issues arise.

### BRIEF DESCRIPTION OF THE DRAWINGS

Aspects of the present disclosure are best understood from the following detailed description w % ben read with the accompanying figures. It should be noted that, in accordance with the standard practice in the industry, various features are not drawn to scale. In fact, the dimensions of the various features may be arbitrarily increased or reduced for clarity of discussion.

FIG. 1 is a flowchart representing a method for forming a semiconductor structure according to aspects of the present disclosure.

FIGS. 2 to 17B are cross-sectional views illustrating a semiconductor structure at various fabrication stages according to aspects of the present disclosure in one or more embodiments.

FIGS. 18 to 23B are cross-sectional views illustrating a semiconductor structure at various fabrication stages according to aspects of the present disclosure in one or more embodiments.

FIGS. 24 to 28B are cross-sectional views illustrating a semiconductor structure at various fabrication stages according to aspects of the present disclosure in one or more embodiments.

FIG. 29 is a top view of a portion of a semiconductor structure according to aspects of the present disclosure in one or more embodiments.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” or “about” generally mean within a value or range that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

With ongoing down-scaling of integrated circuits, power supply voltages of the integrated circuits may be reduced. However, the voltage reductions may be different in different circuits or regions. For example, memory circuits and core circuits may have different threshold voltage (Vt) requirements. A multiple-Vt capability may be formed for device design.

Further, as gate length (Lg) scale is reduced in advanced nodes, realizing the multiple-Vt capability using different gate metal materials becomes challenging.

Embodiments of a method for forming a semiconductor structure are therefore provided. The semiconductor structure is formed in an HKMG process with multiple-Vt design. The semiconductor structure can be formed in a planar device process according to some embodiments. The semiconductor structure can be formed in a non-planar device in alternative embodiments. In some embodiments, the method for forming the semiconductor structure includes providing dielectric layers having different thicknesses to provide the multiple-Vt capability. In some embodiments, a thicker dielectric layer is provided for a high voltage (HV) device, while a thinner dielectric layer is provided for a low voltage (LV) device. Further, the method for forming the semiconductor structure includes dielectric pillars or semiconductor pillars in a metal gate structure of an HV device. The semiconductor pillars or dielectric pillars help to mitigate a dishing issue during a planarization in the HKMG process.

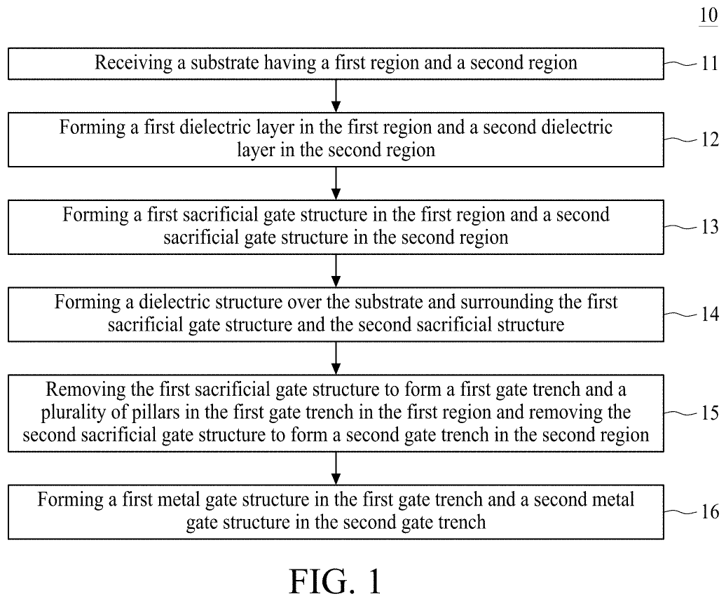

FIG. 1 is a flowchart representing a method for forming a semiconductor structure 10 according to aspects of the present disclosure. The method 10 includes a number of operations (11, 12, 13, 14, 15 and 16). The method 10 will be further described according to one or more embodiments. It should be noted that the operations of the method 10 may be rearranged or otherwise modified within the scope of the various aspects. It should further be noted that additional processes may be provided before, during, and after the method 10, and that some other processes may be only briefly described herein. Thus, other implementations are possible within the scope of the various aspects described herein.

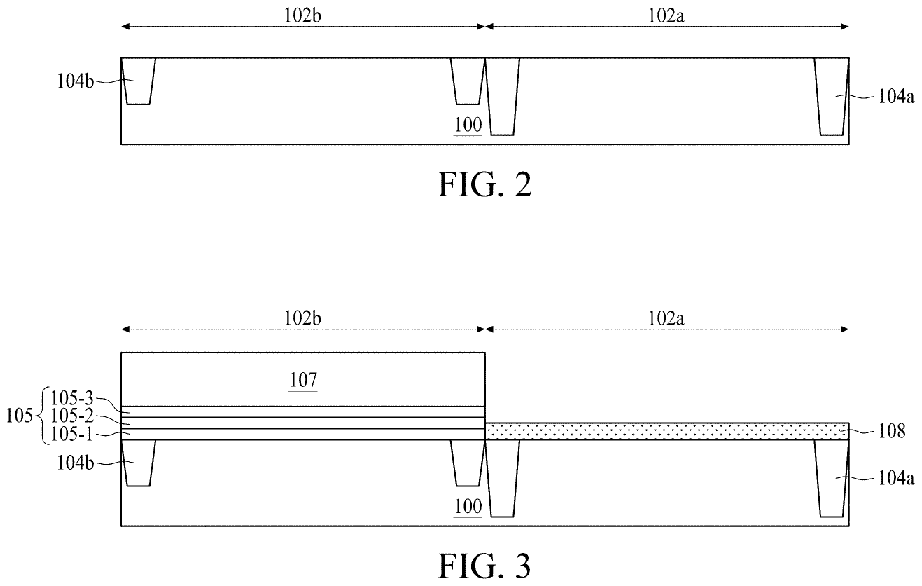

FIGS. 2 to 17B are cross-sectional show cross-sectional views illustrating a semiconductor structure at various fabrication stages according to aspects of the present disclosure in one or more embodiments. Referring to FIG. 2, in operation 11, a substrate 100 is received. In some embodiments, the substrate 100 may be a semiconductor substrate such as a silicon substrate. The substrate 100 may also include other semiconductors such as germanium (Ge), silicon carbide (SiC), silicon germanium (SiGe), or diamond. Alternatively, the substrate 100 may include a compound semiconductor and/or an alloy semiconductor. The substrate 100 may include various doping configurations depending on design requirements, as is known in the art. For example, different doping profiles (e.g., n wells or p wells) may be formed on the substrate 100 in regions designed for different device types (e.g., n-type field-effect transistors (NFET), or p-type field-effect transistors (PFET)). The suitable doping may include ion implantation of dopants and/or diffusion processes.

In some embodiments, the substrate 100 may include a first region 102a and a second region 102b. Further, the substrate 100 may include isolation structures, e.g., shallow trench isolation (STI) structures 104a and 104b defining and interposing the first and second regions 102a and 102b. The first and second regions 102a and 102b are defined for accommodating different devices. For example, the first region 102a may accommodate a HV device, and the second region 102b may accommodate an LV device. In some embodiments, the HV device has an operating voltage greater than that of the LV device. It should be noted that the operating voltages can vary for different applications; thus they are not limited herein. In some embodiments, the HV device and the LV device may be planar transistors or multi-gate transistors, such as fin-like FETs (FinFETs).

The isolation structures 104a and 104b are formed in the substrate 100 for different requirements. For example, the isolation structure 104a with a greater depth is formed to define the first region 102a, and the isolation structures 104b with a smaller depth is formed to define the second region 102b, according to different Vt designs.

In operation 12, a first dielectric layer is formed in the first region 102a and a second dielectric layer is formed in the second region 102b.

In some embodiments, operation 12 includes further operations. For example, a mask layer 105 may be formed over the substrate 100. Further, the mask layer 105 may be patterned to expose the first region 102a through a patterned photoresist 107, as shown in FIG. 3. In some embodiments, the mask layer 105 may include a multilayer hard mask structure. For example but not limited thereto, the mask layer 105 may include a pad oxide layer 105-1, a silicon nitride layer 105-2 and another oxide layer 105-3. In some embodiments, the oxide layer 105-3 may include tetraethoxysilane (TEOS), but the disclosure is not limited thereto.

Still referring to FIG. 3, in some embodiments, a dielectric layer 108 is formed in the first region 102a by, for example but not limited thereto, an in-situ-stream generation (ISSG) oxidation process. Further, the dielectric layer 108 is formed in the first region 102a, while the second region 102b is covered by the patterned photoresist layer 107 and the mask layer 105.

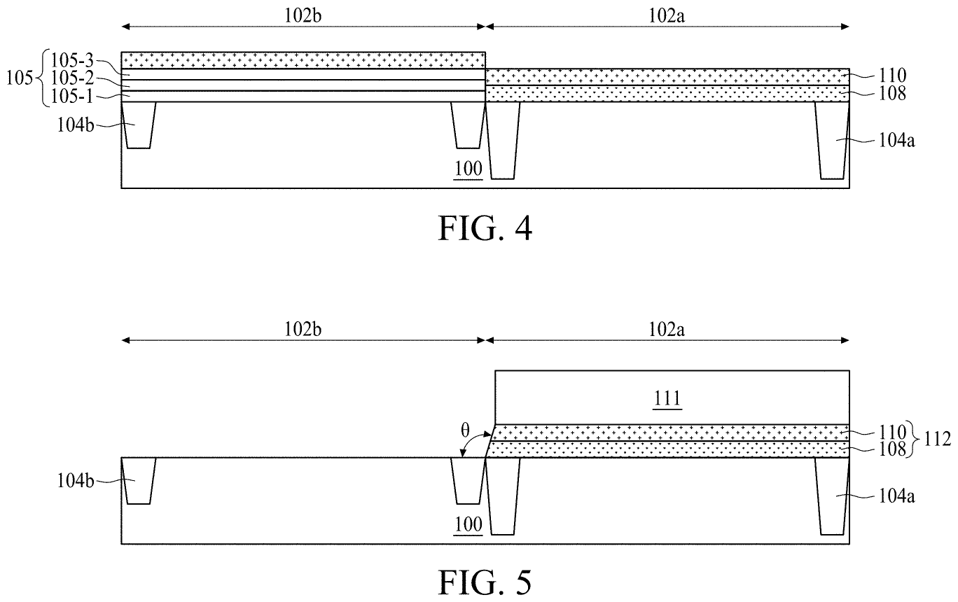

Referring to FIG. 4, in some embodiments, the patterned photoresist layer 107 is removed. Subsequently, a dielectric layer 110 is formed over the substrate 100. In some embodiments, the dielectric layer 110 may be a hot temperature oxide (HTO), but the disclosure is not limited thereto. In some embodiments, the dielectric layer 110 may cover the mask layer 105, but the disclosure is not limited thereto. A thickness of the dielectric layer 108 may be different from that of the dielectric layer 110. In some embodiments, the thickness of the dielectric layer 108 may be greater than that of the dielectric layer 110, but the disclosure is not limited thereto. In some embodiments, the forming of the dielectric layer 110 may be omitted, thus only the dielectric layer 108 is formed in the first region 102a.

Referring to FIG. 5, another mask layer 111, such as a patterned photoresist layer, is formed over the dielectric layer 110 in the first region 102a. Using the mask layer 111 as a protecting layer, the dielectric layer 110 and mask layer 105 are removed from the second region 102b. Consequently, a first dielectric layer 112 is formed in the first region 102a. In some embodiments, the first dielectric layer 112 may include only one layer (i.e., the dielectric layer 108). In other embodiments, the first dielectric layer 112 may include multiple layers (i.e., the dielectric layer 108 and the dielectric layer 110). In some embodiments, a thickness of the first dielectric layer 112 can be adjusted according to different device requirements or voltage requirements. For example, for an HV device operating at a voltage equal to or greater than 5V, the thickness of the first dielectric layer 112 is greater than approximately 130 angstroms, but the disclosure is not limited thereto.

Still referring to FIG. 5, the substrate 100 in the second region 102b is exposed after the removing of the dielectric layer 110 and the mask layer 105 from the second region 102b. In some embodiments, during the removing of the dielectric layer 110 and the mask layer 105, the first dielectric layer 112 may obtain a tilted sidewall, as shown in FIG. 5. The tilted sidewall has an included angle θ. In some embodiments, the included angle θ is less than 45°, but the disclosure is not limited thereto.

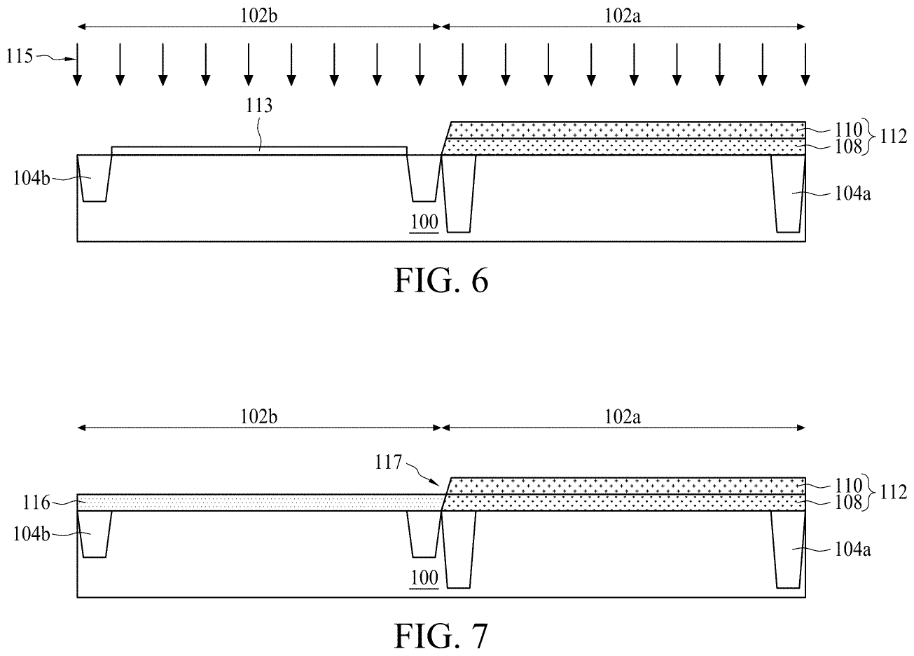

Referring to FIG. 6, in some embodiments, the mask layer 111 is removed after the removing of the dielectric layer 110 and the mask layer 105. In some embodiments, a sacrificial oxide layer 113 may be formed over the substrate 100 in the second region 102b, but the disclosure is not limited thereto. In some embodiments, an ion implantation 115 may be performed to form a well region (not shown) in the second region 102b. In such embodiments, the substrate 100 in the first region 102a is protected from the ion implantation 115 by the first dielectric layer 112.

Referring to FIG. 7, in some embodiments, the sacrificial oxide layer 113 is removed, and a second dielectric layer 116 is formed in the second region 102b. The second dielectric layer 116 may include silicon oxide, but the disclosure is not limited thereto. Further, a thickness of the second dielectric layer 116 is less than the thickness of the first dielectric layer 112. In some embodiments, a tilted step 117 is formed at a boundary between the first dielectric layer 112 and the second dielectric layer 116. In some embodiments, a height difference between a top surface (i.e., a top surface of the first dielectric layer 112) and a bottom surface (i.e., atop surface of the second dielectric layer 116) of the tilted step 117 is less than 40 nanometers, but the disclosure is not limited thereto.

In some embodiments, in operation 13, a first sacrificial gate structure is formed in the first region 102a, and a second sacrificial gate structure is formed in the second region 102b.

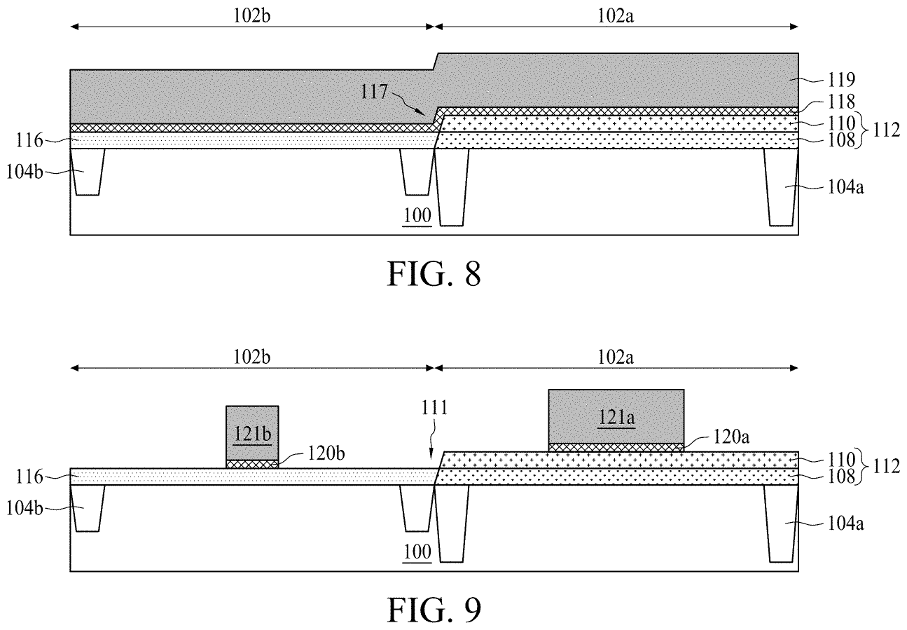

In some embodiments, operation 13 includes further operations. For example, a high-k dielectric layer 118 is formed over the first dielectric layer 112, the second dielectric layer 116 and the tilted step 117, and a sacrificial layer 119 is formed over the high-k dielectric layer 118, as shown in FIG. 8. In some embodiments, the high-k dielectric layer 118 includes a high-k dielectric material having a high dielectric constant, for example, a dielectric constant greater than that of thermal silicon oxide (3.9). The high-k dielectric material may include hafnium oxide (HfO₂), zirconium oxide (ZrO₂), lanthanum oxide (La₂O₃), aluminum oxide (Al₂O₃), titanium oxide (TiO₂), yttrium oxide (Y₂O₃), strontium titanate (SrTiO₃), hafnium oxynitride (HfOxNy), other suitable metal-oxides, or combinations thereof. In some embodiments, the sacrificial layer 119 may include semiconductor material such as, for example but not limited thereto, polysilicon.

Referring to FIG. 9, in some embodiments, a patterned hard mask layer (not shown) is formed over the sacrificial layer 119, and a suitable etching operation is performed to remove portions of the sacrificial layer 119 and portions of the high-k dielectric layer 118. Thus, a first sacrificial gate structure 121a is formed in the first region 102a, and a second sacrificial gate structure 121b is formed in the second region 102b. The high-k dielectric layer 118 is also patterned to form a first high-k dielectric layer 120a under the first sacrificial gate structure 121a, while a second high-k dielectric layer 120b is formed under the second sacrificial gate structure 121b. Further, a width of the first sacrificial gate structure 121a is greater than a width of the second sacrificial gate structure 121b. In some embodiments, portions of the first dielectric layer 112 are exposed through the first sacrificial gate structure 121a in the first region 102a, and portions of the second dielectric layer 116 are exposed through the second sacrificial gate structure 121b in the second region 102b.

It should be noted that in some comparative approach, when the included angle θ of tiled sidewall of the first dielectric layer 112 is greater than 90°, a high-k residue is easily found at the tilted step 117. Comparing the tilted step 117 formed by the first dielectric layer 112 having the include angle θ less than 0° to that of the comparative approach, the high-k residue issue is mitigated.

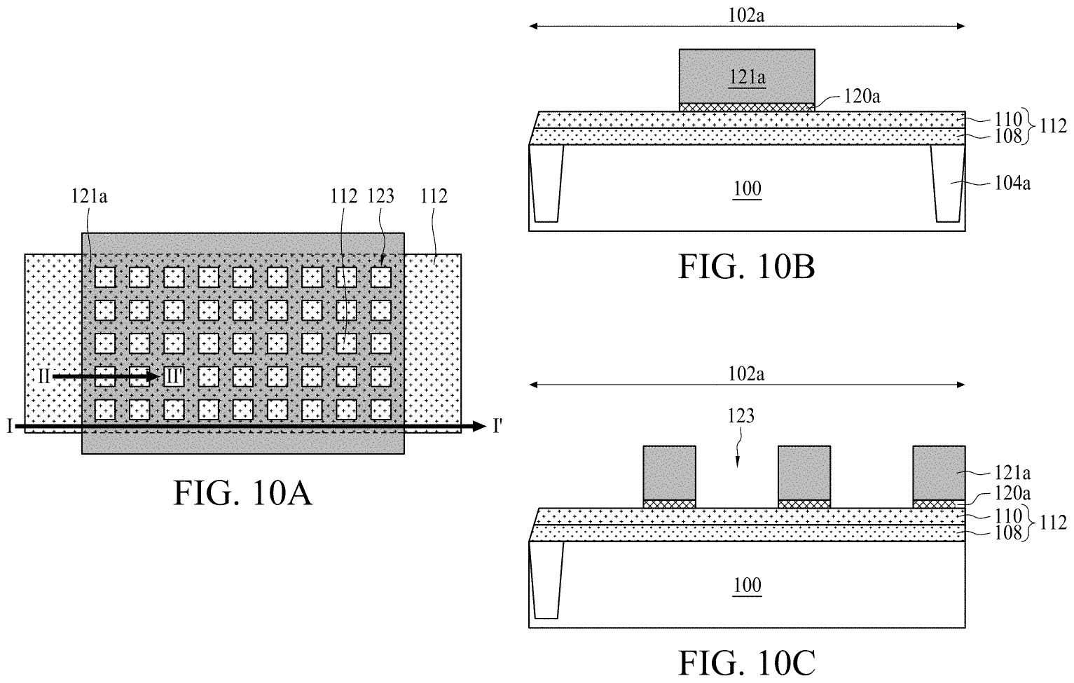

Referring to FIGS. 10A to 10C, wherein FIG. 10A is a top view of the first region 102a, FIG. 10B is a cross-sectional view taken along line I-I′ of FIG. 10A, and FIG. 10C is a cross-sectional view taken along line II-II′ of FIG. 10A, a plurality of openings 123 are formed in the first sacrificial gate structure 121a. In some embodiments, the first sacrificial gate structure 121a and the openings 123 are simultaneously formed. The openings 123 are separated from each other by the first sacrificial gate structure 121a. Further, portions of the first dielectric layer 112 are exposed through bottoms of the openings 123, as shown in FIG. 10C. In some embodiments, the openings 123 have a square shape, but the disclosure is not limited thereto. In some embodiments, widths and lengths of the openings 123 are similar to each other, but the disclosure is not limited thereto. In some embodiments, the openings 123 are periodically arranged, as shown in FIG. 10A, but the disclosure is not limited thereto. For example, the openings 123 may be randomly arranged, though not shown.

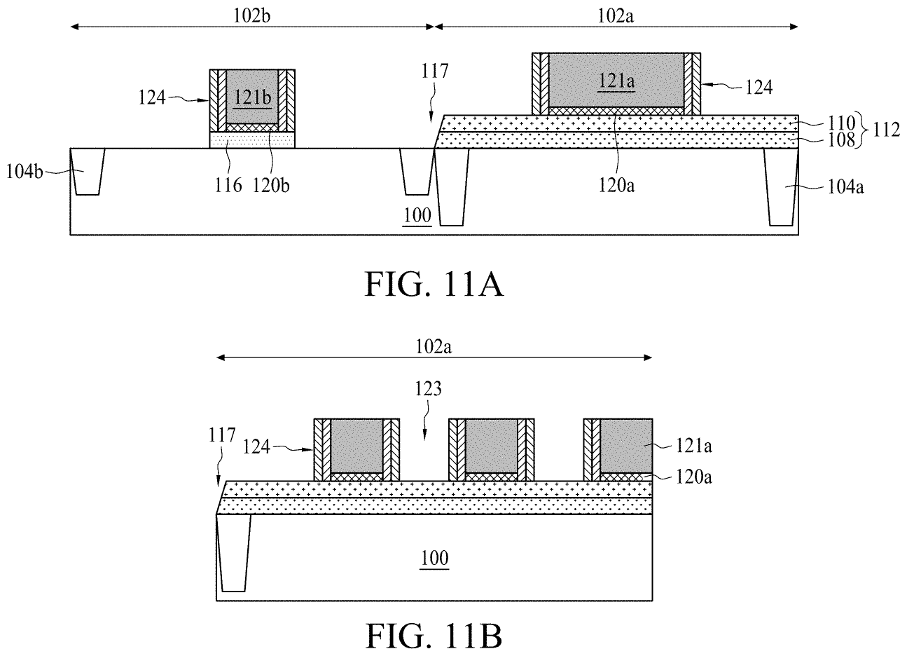

Referring to FIGS. 11A and 11B, in some embodiments, spacers 124 are formed over sidewalls of the sacrificial gate structures 121a and 121b. Further, the spacers 124 are formed over sidewalls of each of the openings 123, as shown in FIG. 11B. In some embodiments, the spacers 124 include multiple layers, but the disclosure is not limited thereto. In some embodiments, the spacers 124 are made of silicon nitride (SiN), silicon carbide (SiC), silicon oxide (SiOₓ), silicon oxynitride (SiON), silicon carbide or any other suitable material, but the disclosure is not limited thereto. In some embodiments, the spacers 124 are formed by deposition and etch-back operations.

Still referring to FIGS. 11A and 11B, another etching operation may be performed. Thus, portions of the second dielectric layer 116 exposed through the second sacrificial gate structure 121b are removed, and portions of the substrate 100 in the second region 102b are exposed, as shown in FIG. 11A. In some embodiments, a protecting layer (not shown) may be formed to protect the first sacrificial gate structure 121a and the first dielectric layer 112 from the abovementioned etching, but the disclosure is not limited thereto.

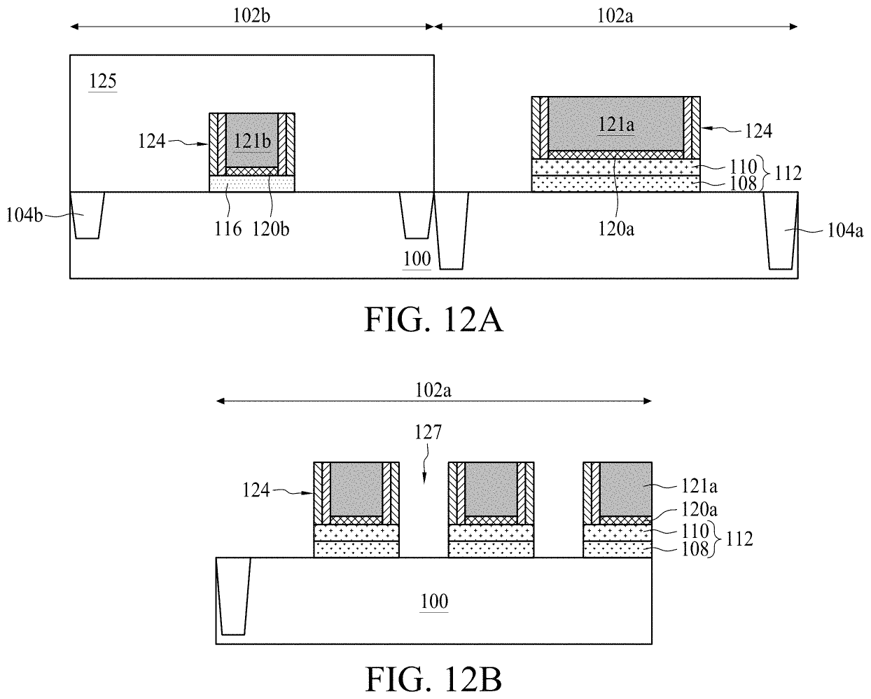

Referring to FIGS. 12A and 12B, in some embodiments, a protecting layer 125, such as a patterned photoresist layer, may be formed in the second region 102b. Another etching may be performed to remove portions of the first dielectric layer 112. Accordingly, the openings 123 are deepened to form a plurality of openings 127. Further, portions of the substrate 100 in the first region 102a are exposed through the first sacrificial gate structure 121a and bottoms of the openings 127 as shown in FIGS. 12A and 12B. Additionally, the tilted step 117 is removed during the removing of the portion of the first dielectric layer 112.

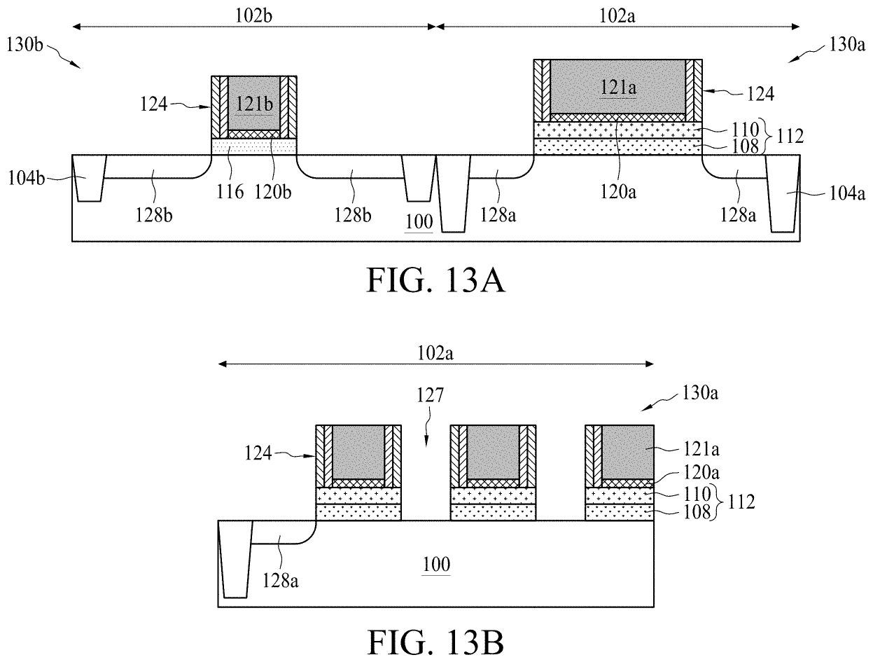

Referring to FIGS. 13A and 13B, in some embodiments, a first source/drain 128a is formed in the first region 102a at opposite sides of the first sacrificial gate structure 121a. A second source/drain 128b is formed in the second region 102b at opposite sides of the second sacrificial gate structure 121b. In some embodiments, tops of the first source/drain 128a and the second source/drain 128b may be higher than a top surface of the substrate 100. In such embodiments, the first source/drain 128a and the second source/drain 128b may be formed by forming recesses in the substrate 100 and growing a strained material in the recesses by an epitaxial (epi) process. In addition, a lattice constant of the strained material may be different from a lattice constant of the substrate 100. Accordingly, the first source/drain 128a and the second source/drain 128b may serve as stressors that improve carrier mobility. In some embodiments, the first source/drain 128a and the second source/drain 128b may include dopants of a same type. However, a dopant concentration of the first source/drain 128a may be different from a dopant concentration of the second source/drain 128b, but the disclosure is not limited thereto. Accordingly, an HV device 130a is formed in the first region 102a, and an LV device 130b is formed in the second region 102b.

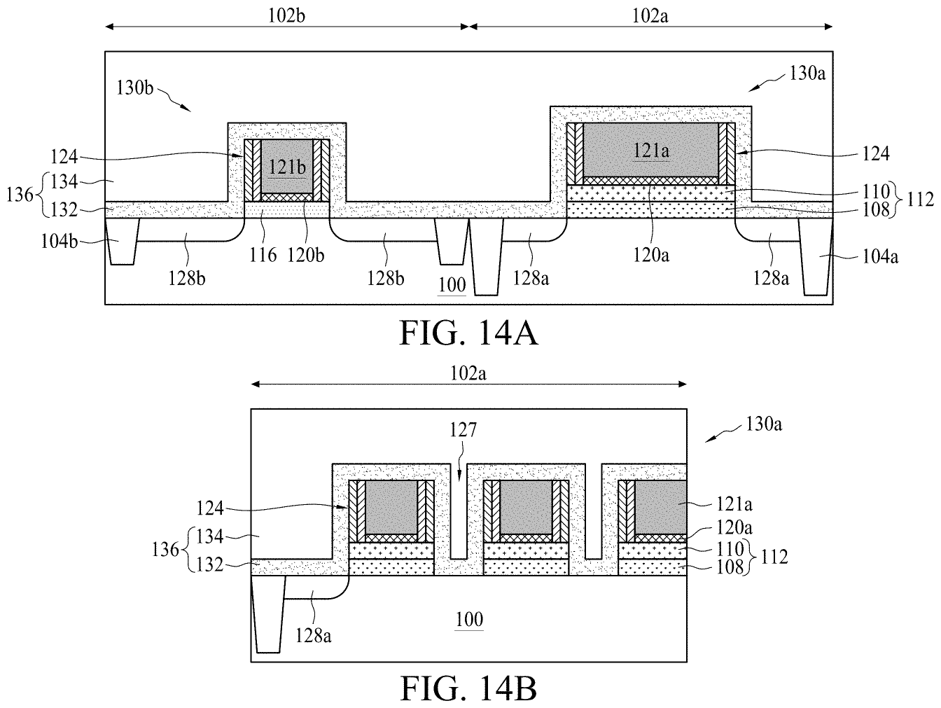

In operation 14, a dielectric structure is formed over the substrate 100. In some embodiments, the operation 14 includes further operations. Referring to FIGS. 14A and 14B, in some embodiments, after the forming of the sources/drains 128a and 128b, a contact etch stop layer (CESL) 132 may be formed to cover the HV and LV devices 130a and 130b over the substrate 100. In some embodiments, the CESL 132 can include silicon nitride, silicon oxynitride, and/or other applicable materials. The CESL 132 may cover the exposed surface of the substrate 100, sidewalls of the first dielectric layer 112, sidewalls of the second dielectric layer 116, the spacers 124, a top surface of the first sacrificial gate structure 121a, a top surface of the second sacrificial gate structure 121b, and sidewalls and the bottoms of the openings 127.

Subsequently, an inter-layer dielectric (ILD) layer 134 is formed on the CESL 132. The ILD layer 134 may include multilayers made of multiple dielectric materials, such as silicon oxide, silicon nitride, silicon oxynitride, tetraethoxysilane (TEOS), phosphosilicate glass (PSG), borophosphosilicate glass (BPSG), low-k dielectric material, and/or other applicable dielectric materials. Examples of low-k dielectric materials include, but are not limited to, fluorinated silica glass (FSG), carbon-doped silicon oxide, amorphous fluorinated carbon, parylene, bis-benzocyclobutenes (BCB), and polyimide.

In some embodiments, the CESL 132 and the ILD layer 134 form the dielectric structure 136 over the substrate 100. Further, the openings 127 are filled with the dielectric structure 136, as shown in FIGS. 14A and 14B.

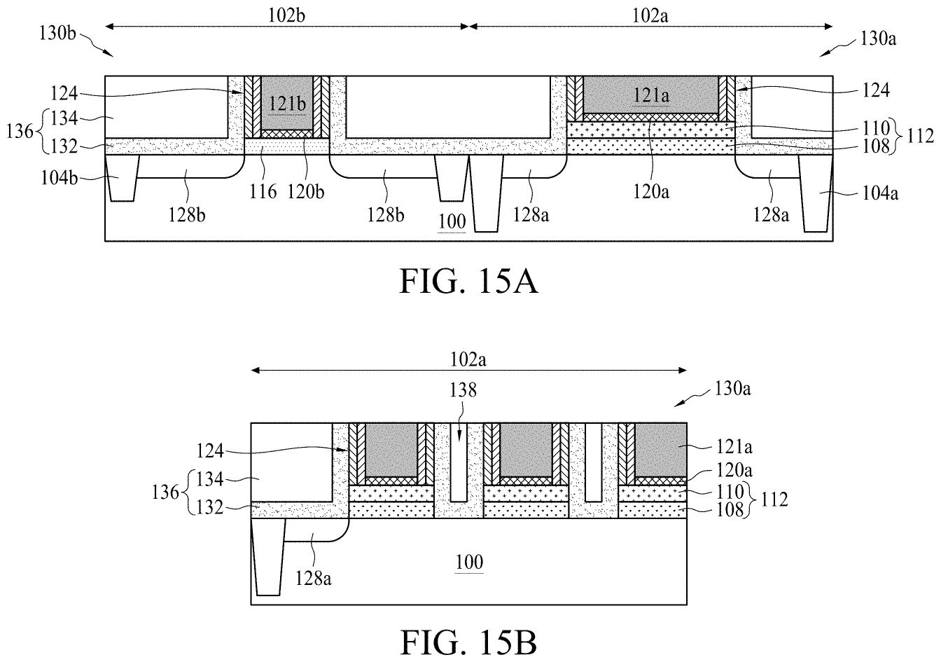

Referring to FIGS. 15A and 15B, next, a planarization is performed on the dielectric structure 136 (i.e., the ILD layer 134 and the CESL 132) to expose top surfaces of the sacrificial gate structures 121a and 121b. In some embodiments, the ILD layer 134 and the CESL 132 are planarized by a chemical mechanical polishing (CMP) process until the top surfaces of the sacrificial gate structures 121a and 121b are exposed. The dielectric structure 136 surrounds the sacrificial gate structures 121a and 121b after the planarization, as shown in FIG. 15A. In some embodiments, portions of the dielectric structure 136 remaining in the openings 127 are referred to as a plurality of dielectric pillars 138, as shown in FIG. 15B. Further, the dielectric pillars 138 are separated from each other by the first sacrificial gate structure 121a.

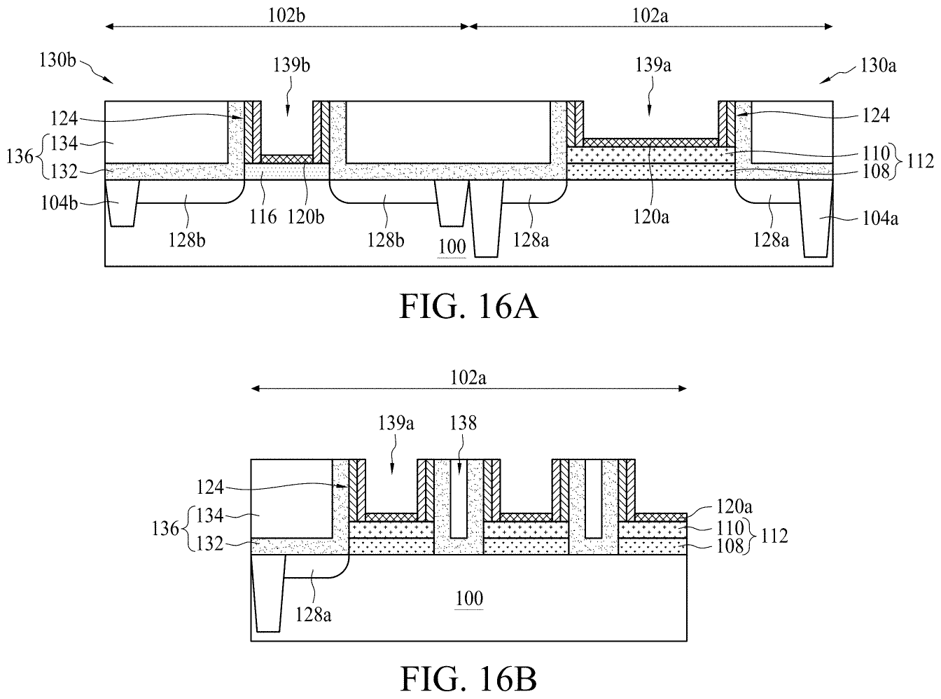

In some embodiments, in operation 15, the first and second sacrificial gate structures 121a and 121b are removed. As shown in FIGS. 16A and 16B, the first sacrificial gate structure 121a is removed to form a first gate trench 139a in the first region 102a, and the second sacrificial gate structure 121b is removed to form a second gate trench 139b in the second region 102b. Further, the dielectric pillars 138 are disposed in the first gate trench 139a as shown in FIG. 16B. In some embodiments, the first high-k dielectric layer 120a is exposed through a bottom of the first gate trench 139a, and the second high-k dielectric layer 120b is exposed through a bottom of the second gate trench 139b.

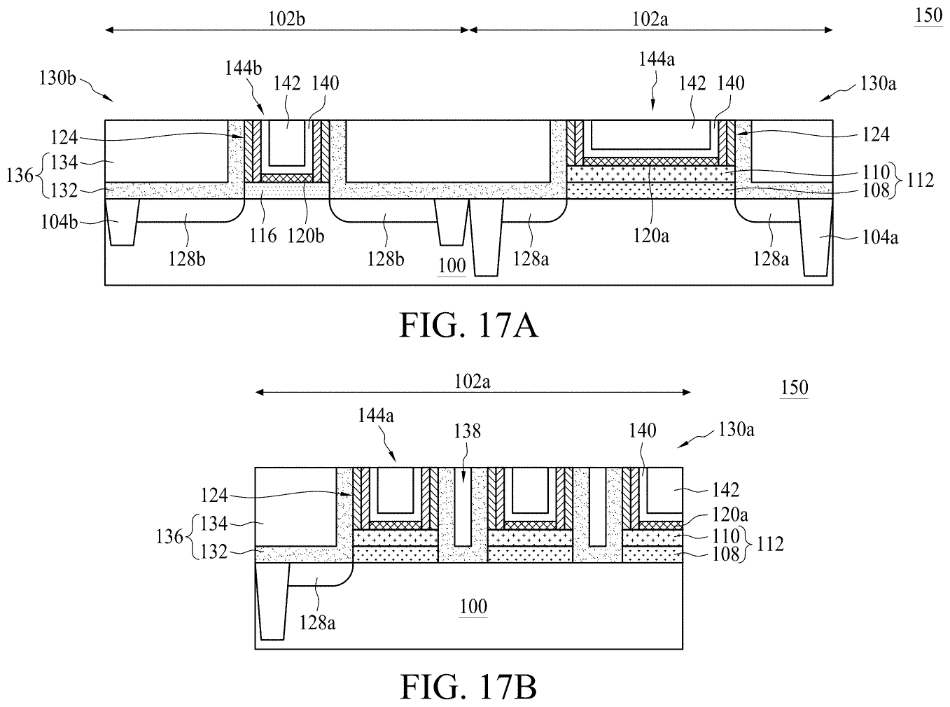

In some embodiments, in operation 16, a first metal gate structure is formed in the first gate trench 139a, and a second metal gate structure is formed in the second gate trench 139b. In some embodiments, the operation 16 includes further operations. Referring to FIGS. 17A and 17B, in some embodiments, a work function metal layer 140 is formed in the first gate trench 139a and the second gate trench 139b. The work function metal layer 140 may include n-type work function metal or p-type work function metal, depending on the product requirements. In some embodiments, the work function metal layer 140 may include a single layer. In some alternative embodiments, the work function metal layer 140 may include a multilayered structure.

Referring to FIGS. 17A and 17B, in some embodiments, a gap-filling metal layer 142 is formed to fill the first gate trench 139a and the second gate trench 139b. In some embodiments, the gap-filling metal layer 142 can include conductive material such as Al, Cu, AICu, or W, but is not limited to the such materials. A planarization operation such as a CMP may be performed to remove superfluous layers. Accordingly, portions of the work function metal layer 140 and portions of the gap-filling metal layer 142 are removed. Thus, a first metal gate structure 144a is formed in the first region 102a and a second metal gate structure 144b is formed in the second region 102b. Further, the dielectric pillars 138 are separated from each other by the first metal gate structure 144a, and a top surface of the first metal gate structure 144a and top surfaces of the dielectric pillars 138 are aligned with each other.

It should be noted that in some comparative approaches, because the width of the first sacrificial gate structure 121a is greater than the width of the second sacrificial gate structure 121b, a width of the gap-filling metal layer 142 in the first region 120a is greater than a width of t the gap-filling metal layer 142 in the second region 102b. Thus, a dishing issue may be found in the gap-filling metal layer 142 of the first metal gate structure 144a due to a greater polishing area. In contrast with the comparative approaches, the dielectric pillars 138 of the present disclosure help mitigate the dishing issue by reducing the polishing area of the gap-filling metal layer 142.

Accordingly, a semiconductor structure 150 is obtained as shown in in FIGS. 17A 17B. The semiconductor structure 150 includes the substrate 100, the HV device 130a disposed in the first region 102a and the LV device 130b disposed in the second region 102b. The HV device 130a includes the first metal gate structure 144a, the first high-k dielectric layer 120a, the first dielectric layer 112, the first source/drain 128a, and the spacers 124. The LV device 130b includes the second metal gate structure 144b, the second high-k dielectric layer 120b, the second dielectric layer 116, the second source/drain 128b, and the spacers 124. Further, the semiconductor structure 150 includes the plurality of dielectric pillars 138 disposed in the first metal gate structure 144a. As mentioned above, the thickness of the first dielectric layer 112 is greater than the thickness of the second dielectric layer 116 for providing the multiple-Vt capability. Further, the first dielectric layer 112 and the second dielectric layer 116 include materials different from that of the high-k dielectric layer 120a and 120b. The dielectric pillars 138 may include the CESL 132 and the ILD layer 134. In some embodiments, a height of the dielectric pillars 138 is substantially equal to a sum of a height of the first metal gate structure 144a and the thickness of the first dielectric layer 112.

In some embodiments, the method 10 may be performed to form the semiconductor structure 150. The method 10 may be performed to form another semiconductor structure as described below.

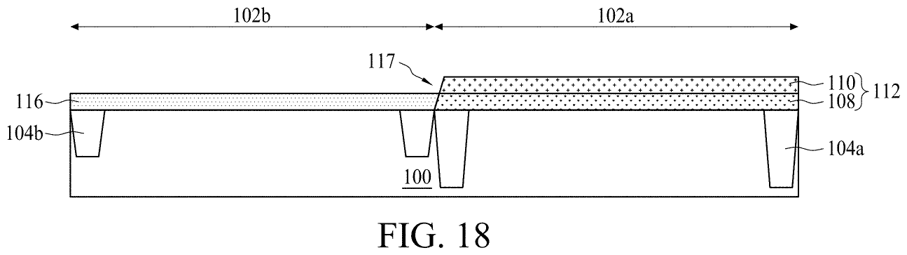

FIGS. 18 to 21B are cross-sectional views illustrating a semiconductor structure at various fabrication stages according to aspects of the present disclosure in one or more embodiments. It should be noted that same elements in FIGS. 2 to 21B are designated by same numerals, and may include same materials. Referring to FIG. 18, in operation 11, a substrate 100 is received. In some embodiments, the substrate 100 may include a first region 102a and a second region 102b. Further, the substrate 100 may include isolation structures, e.g., STI structures 104a and 104b defining and interposing the first and second regions 102a and 102b. The regions 102a and 102b are defined for accommodating different devices. For example, the first region 102a may accommodate a HV device, and the second region 102b may accommodate an LV device. As mentioned above, the HV device used herein is a device having an operating voltage greater than that of the LV device. It should be noted that the operating voltages can vary for different applications, and thus are not limited herein. In some embodiments, the isolation structures 104a and 104b are formed for providing the multiple-Vt capability.

Still referring to FIG. 18, in operation 12, a first dielectric layer 112 is formed in the first region 102a and a second dielectric layer 116 is formed in the second region 102b. In some embodiments, operation 12 include further operations, and those operations may be similar to those shown in FIGS. 2 to 7; therefore, repeated descriptions are omitted for brevity. As mentioned above, a tilted step 117 may be formed at a boundary between the first dielectric layer 112 and the second dielectric 116, as shown in FIG. 18.

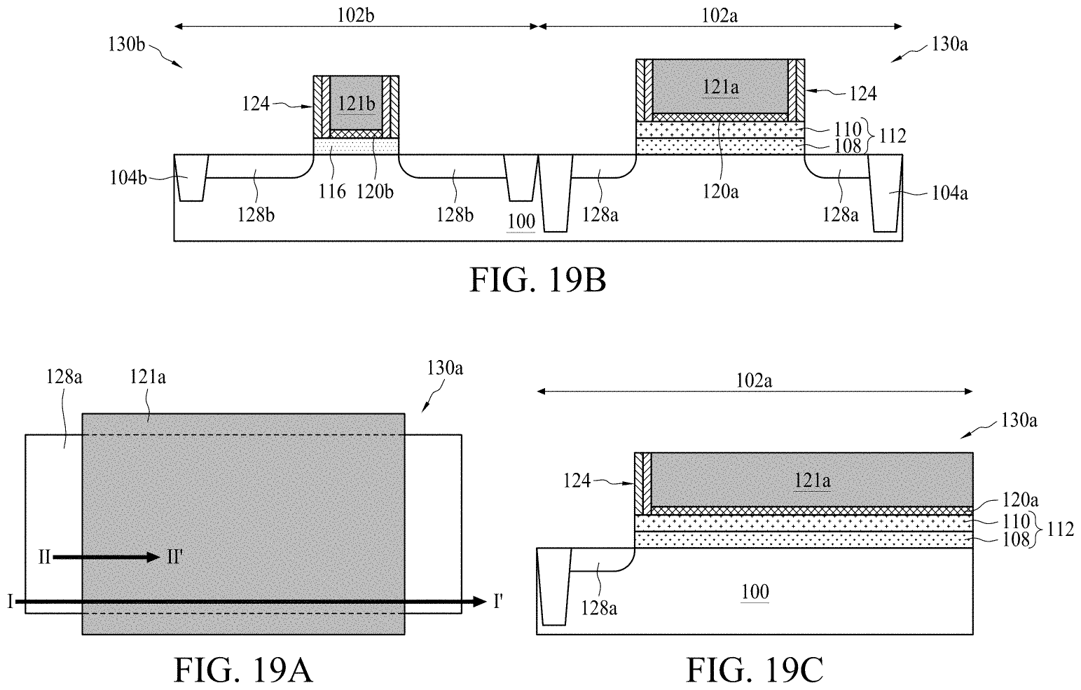

In operation 13, a first sacrificial gate structure 121a is formed in the first region 102a, and a second sacrificial gate structure 121b is formed in the second region 102b. In some embodiments, operation 13 includes further operations. For example, a high-k dielectric layer and a sacrificial layer may be sequentially formed over the substrate 100. A patterning operation is performed to remove portions of the high-k dielectric layer and the sacrificial layer, thus forming the first sacrificial gate structure 121a is formed in the first region 102a and the second sacrificial gate structure 121b in the second region 102b. Further, portions of the high-k dielectric layer are removed, while a portion of the high-k dielectric layer 120a remains between the first dielectric layer 112 and the first sacrificial gate structure 121a and a portion of the high-k dielectric layer 120b remains between the second dielectric layer 116 and the second sacrificial gate structure 121b. As mentioned above, due to the tilted step 117, a high-k residue issue may be mitigated. It should be noted that a width of the first sacrificial gate structure 121a is greater than a width of the second sacrificial gate structure 121b, as shown in FIG. 19B.

In some embodiments, after the forming of the first and second sacrificial gate structures 121a and 121b, spacers 124 are formed over sidewalls of the first and second sacrificial gate structures 121a and 121b. A first source/drain 128a is formed in the first region 102a at opposite sides of the first sacrificial gate structure 121a, and a second source/drain 128b is formed in second region 102b at opposite sides of the second sacrificial gate structure 121b. In some embodiments, the first source/drain 128a and the second source/drain 128b may serve as stressors that improve carrier mobility. In some embodiments, the first source/drain 128a and the second source/drain 128b may include dopants of a same type. However, a dopant concentration of the first source/drain 128a may be different from a dopant concentration of the second source/drain 128b, but the disclosure is not limited thereto. Accordingly, an HV device 130a is formed in the first region 102a, and an LV device 130b is formed in the second region 102b, as shown in FIGS. 19A to 19C.

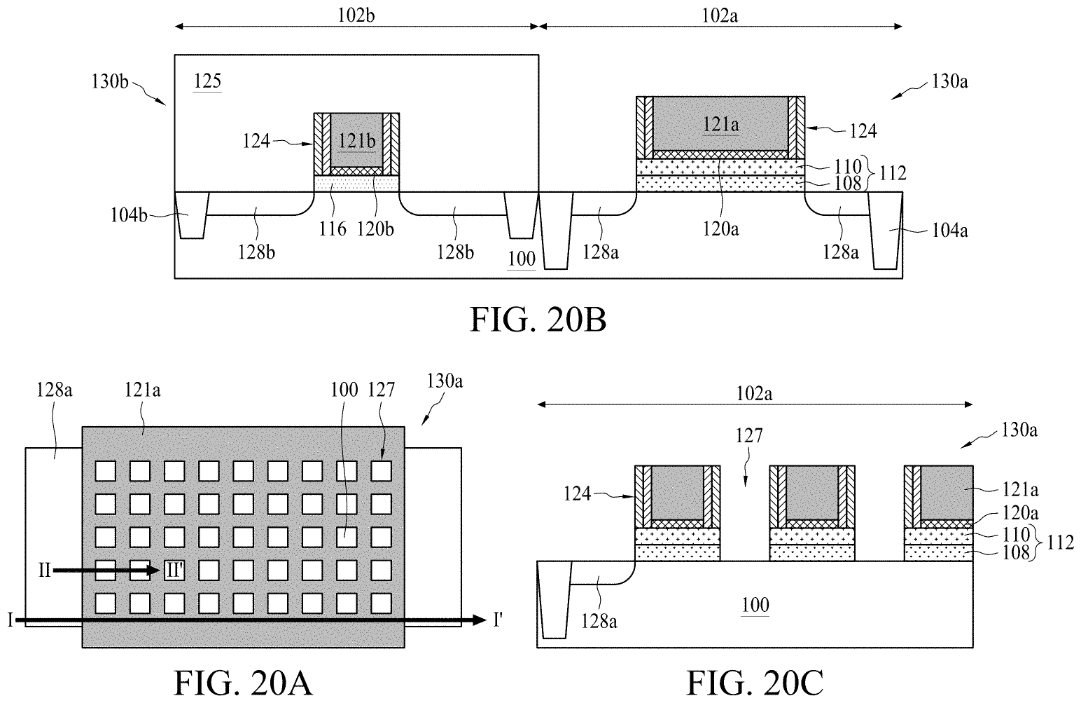

Referring to FIGS. 20A to 20C, in some embodiments, a protecting layer 125, such as a patterned photoresist layer, may be formed in the second region 102b. An etching operation may be performed to remove portions of the first sacrificial gate structure 121a, portions of the high-k dielectric layer 120a and portions of the first dielectric layer 112. Accordingly, a plurality of openings 127 are formed. In other words, the openings 127 are formed after the forming of the first and second sacrificial gate structures 121a and 121b. Further, portions of the substrate 100 in the first region 102a are exposed through the first sacrificial gate structure 121a and bottoms of the openings 127 as shown in FIGS. 20A to 20C.

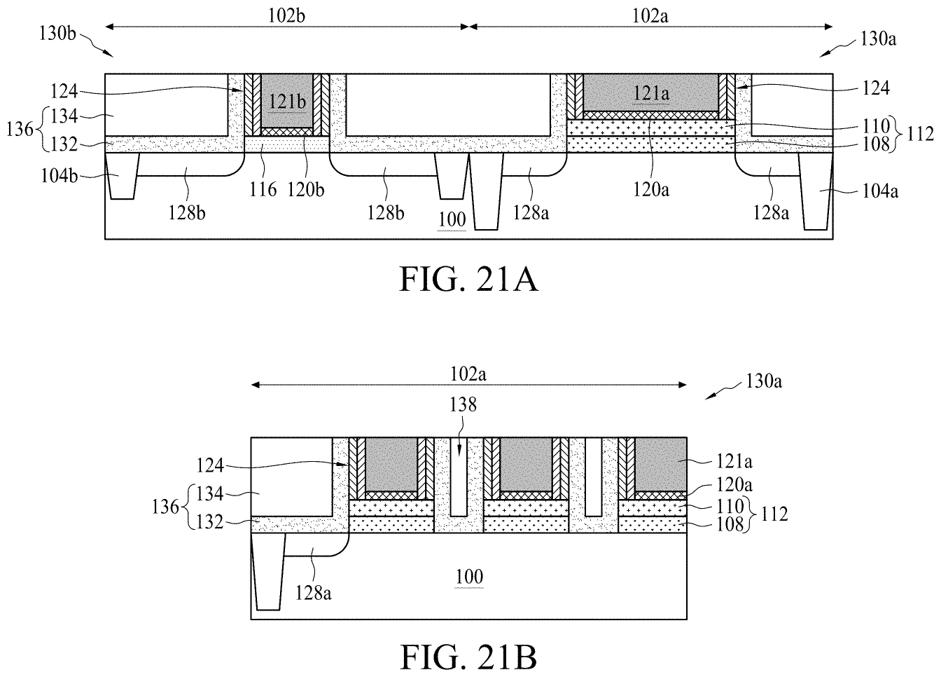

Referring to FIGS. 21A and 21B, a dielectric structure 136 is formed over the substrate 100 in operation 14. The dielectric structure 136 covers the LV and HV devices 130a and 130b. In some embodiments, the operation 14 includes further operations. As mentioned above, a CESL 132 is formed to cover the HV and LV devices 130a and 130b over the substrate 100. The CESL 132 may cover the exposed surface of the substrate 102, sidewalls of the first dielectric layer 112, sidewalls of the second dielectric layer 116, the spacers 124, a top surface of the first sacrificial gate structure 121a, a top surface of the second sacrificial gate structure 121b, and sidewalls and the bottoms of the openings 127. Subsequently, an ILD layer 134 is formed on the CESL 132 in accordance with some embodiments. The CESL 132 and the ILD layer 134 form the dielectric structure 136 over the substrate 100. Further, the openings 127 are filled with the dielectric structure 136.

Next, a planarization is performed on the dielectric structure 136 to expose top surfaces of the sacrificial gate structures 121a and 121b. In some embodiments, after the planarization, portions of the dielectric structure 136 remaining in the openings 127 are referred to as a plurality of dielectric pillars 138. As shown in FIG. 21B, the dielectric pillars 138 are separated from each other by the first sacrificial gate structure 121a.

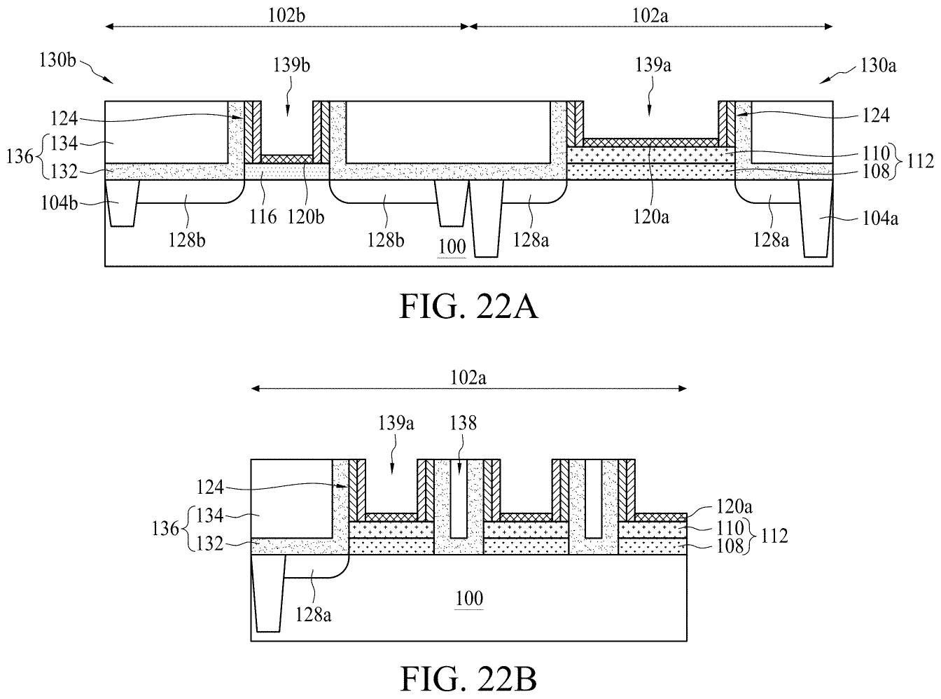

Referring to FIGS. 22A and 22B, in operation 15, the first sacrificial gate structure 121a is removed to form a first gate trench 139a in the first region 102a, and the second sacrificial gate structure 121b is removed to form a second gate trench 139b in the second region 102b. Further, the dielectric pillars 138 are disposed in the first gate trench 139a, as shown in FIG. 22B. In some embodiments, the high-k dielectric layer 120a is exposed through a bottom of the first gate trench 139a, and the high-k dielectric layer 120b is exposed through a bottom of the second gate trench 139b.

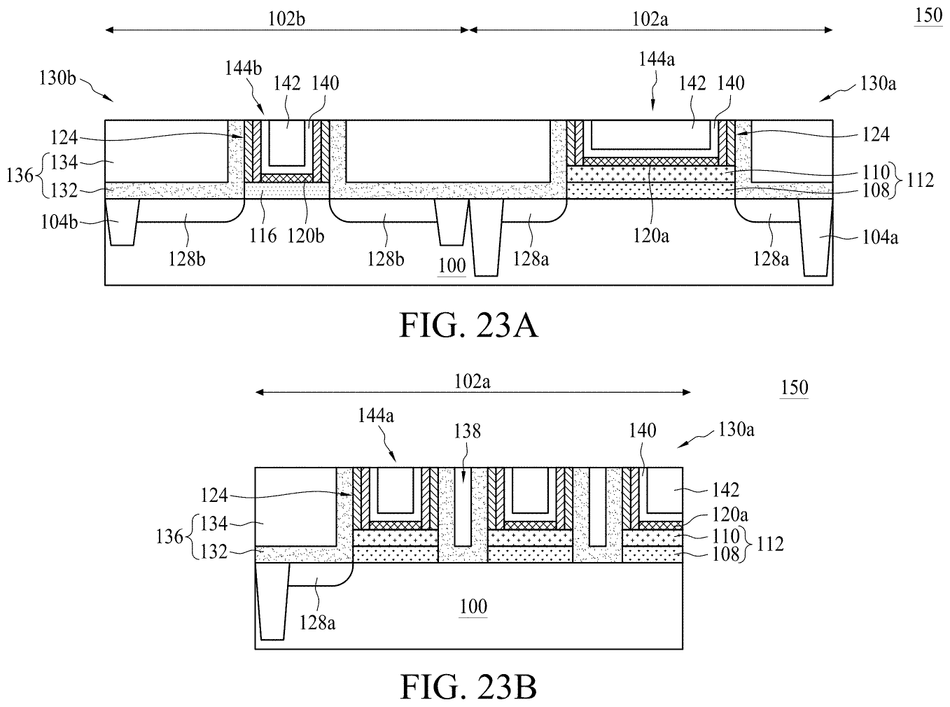

Referring to FIGS. 23A and 23B, in operation 16, a first metal gate structure 144a is formed in the first gate trench 139a, and a second metal gate structure 144b is formed in the second gate trench 139b. In some embodiments, the operation 16 includes further operations. As mentioned above, a work function metal layer 140 is formed in the first gate trench 139a and the second gate trench 139b. The work function metal layer 140 may include n-type work function metal or p-type work function metal, depending on the product requirements. In some embodiments, the work function metal layer 140 may include a single layer. In some alternative embodiments, the work function metal layer 140 may include a multilayered structure.

A gap-filling metal layer 142 is formed to fill the first gate trench 139a and the second gate trench 139b. In some embodiments, the gap-filling metal layer 142 can include conductive material such as Al, Cu, AlCu, or W, but is not limited to such materials. A planarization operation such as a CMP may be performed to remove superfluous layers. Accordingly, portions of the work function metal layer 140 and portions of the gap-filling metal layer 142 are removed. Thus, the first metal gate structure 144a is formed in the first region 102a and the second metal gate structure 144b is formed in the second region 102b. Further, the dielectric pillars 138 are separated from each other by the first metal gate structure 144a, and a top surface of the first metal gate structure 144a and top surfaces of the dielectric pillars 138 are aligned with each other, as shown in FIG. 23B.

As mentioned above, in comparative approaches, because the width of the first sacrificial gate structure 121a is greater than the width of the second sacrificial gate structure 121b, a width of the gap-filling metal layer 142 in the first region 120a is greater than a width of the gap-filling metal layer 142 in the second region 102b. Thus, a dishing issue may be found in the gap-filling metal layer 142 of the first metal gate structure 144a due to a greater polishing area. In contrast with the comparative approaches, the dielectric pillars 138 helps mitigate the dishing issue by reducing the polishing area of the gap-filling metal layer 142.

Accordingly, a semiconductor structure 150 is obtained as shown in in FIGS. 23A and 23B. The semiconductor structure 150 including the dielectric pillars 138 in the first metal gate structure 144a includes elements same as those shown in FIGS. 17A and 17B, and repeated description are therefore omitted for brevity.

In some embodiments, the method 10 may be performed to form the semiconductor structure 150. The method 10 may be performed to form another semiconductor structure as described below.

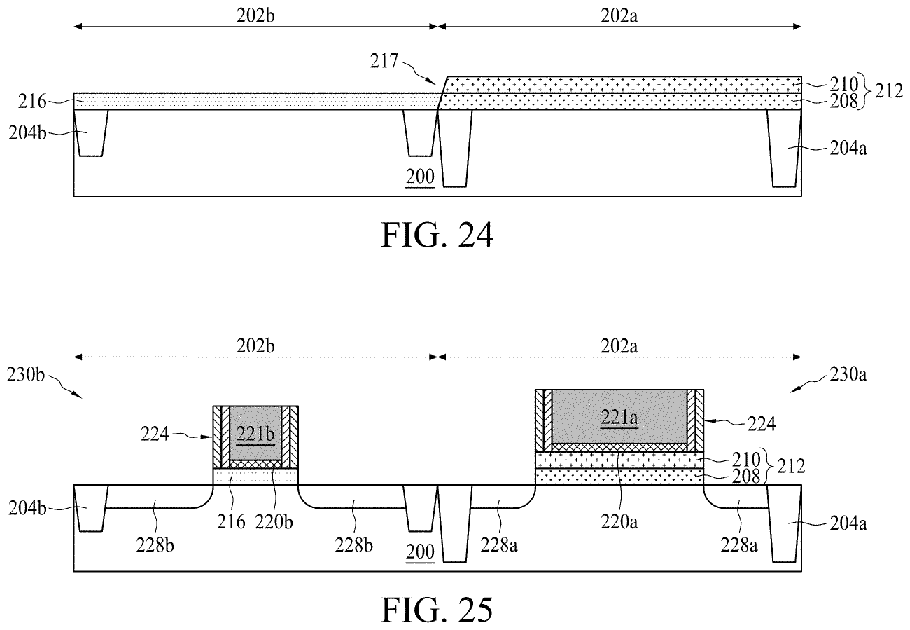

FIGS. 24 to 27B are cross-sectional show cross-sectional views illustrating a semiconductor structure at various fabrication stages according to aspects of the present disclosure in one or more embodiments. It should be noted that same elements in FIGS. 2 to 27B are designated by same numerals, and may include same materials.

Referring to FIG. 24, in some embodiments, in operation 11, a substrate 200 is received. In some embodiments, the substrate 200 may include a first region 202a and a second region 202b. Further, the substrate 200 may include isolation structures, e.g., STI structures 204a and 204b defining and interposing the first and second regions 202a and 202b. The regions 202a and 202b are defined for accommodating different devices. For example, the first region 202a may accommodate an HV device, and the second region 2102b may accommodate an LV device. As mentioned above, the HV has an operating voltage greater than that of the LV device. It should be noted that the operating voltages can vary for different applications, and thus are not limited herein. The isolation structures 204a and 204b can be formed in different regions for different requirements. In some embodiments, the isolation structures 104a and 104b are formed for providing the multiple-Vt capability.

Still referring to FIG. 24, in operation 12, a first dielectric layer 212 is formed in the first region 202a and a second dielectric layer 216 is formed in the second region 202b. In some embodiments, operation 12 include further operations, and those operations may be similar to those shown in FIGS. 2 to 7; therefore, repeated descriptions are omitted for brevity. As mentioned above, a tilted step 217 may be formed at a boundary between the first dielectric layer 212 and the second dielectric layer 216.

Referring to FIG. 25, in operation 13, a first sacrificial gate structure 221a is formed in the first region 202a, and a second sacrificial gate structure 221b is formed in the second region 202b. In some embodiments, operation 13 includes further operations. For example, a high-k dielectric layer and a sacrificial layer may be sequentially formed over the substrate 200. A patterning operation is performed to remove portions of the high-k dielectric layer and the sacrificial layer, thus formed the first sacrificial gate structure 221a in the first region 202a, and the second sacrificial gate structure 221b in the second region 202b. Further, portions of the high-k dielectric layer are removed, while a portion of the high-k dielectric layer 220a remains between the first dielectric layer 212 and the first sacrificial gate structure 221a and a portion of the high-k dielectric layer 220b remains between the second dielectric layer 216 and the second sacrificial gate structure 221b. As mentioned above, due to the tilted step 217, a high-k residue issue may be mitigated. It should be noted that a width of the first sacrificial gate structure 221a is greater than a width of the second sacrificial gate structure 221b, as shown in FIG. 25.

In some embodiments, after the forming of the first and second sacrificial gate structures 221a and 221b, spacers 224 are formed over sidewalls of the first and second sacrificial gate structures 221a and 221b. A first source/drain 228a is formed in the first region 202a at opposite sides of the first sacrificial gate structure 221a, and a second source/drain 228b is formed in second region 202b at opposite sides of the second sacrificial gate structure 221b. In some embodiments, the first source/drain 228a and the second source/drain 228b may serve as stressors that improve carrier mobility. In some embodiments, the first source/drain 228a and the second source/drain 228b may include dopants of a same type. However, a dopant concentration of the first source/drain 228a may be different from a dopant concentration of the second source/drain 228b, but the disclosure is not limited thereto. Accordingly, an HV device 230a is formed in the first region 202a, and an LV device 230b is formed in the second region 202b.

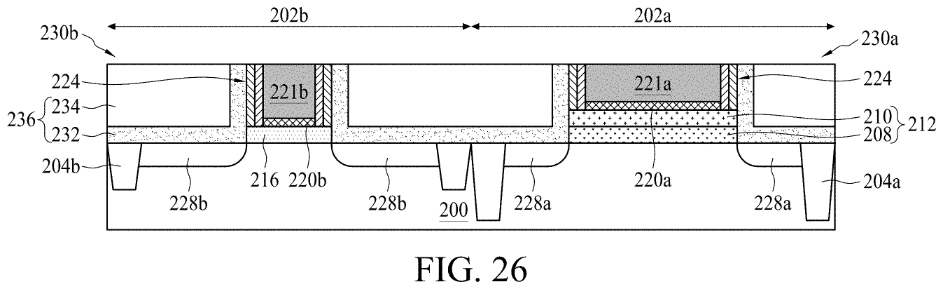

Referring to FIG. 26, a dielectric structure 236 is formed over the substrate 200 in operation 14. The dielectric structure covers the LV and HV devices 230a and 230b. In some embodiments, the operation 14 includes further operations. As mentioned above, a CESL 232 is formed to cover the HV and LV devices 230a and 230b over the substrate 200. The CESL 232 may cover the exposed surface of the substrate 202, sidewalls of the first dielectric layer 212, sidewalls of the second dielectric layer 216, the spacers 224, a top surface of the first sacrificial gate structure 221a, and a top surface of the second sacrificial gate structure 221b. Subsequently, an ILD layer 234 is formed on the CESL 232. The CESL 232 and the ILD layer 234 form the dielectric structure 236 over the substrate 200. Next, a polishing process is performed on the dielectric structure 236 to expose top surfaces of the sacrificial gate structures 221a and 221b.

In some embodiments, in operation 15, portions of the first sacrificial gate structure 221a are removed to form a first gate trench 239a in the first region 202a, and the second sacrificial gate structure 221b is removed to form a second gate trench 239b in the second region 202b. In some embodiments, the high-k dielectric layer 220a is exposed through a bottom of the first gate trench 239a, and the high-k dielectric layer 220b is exposed through a bottom of the second gate trench 239b.

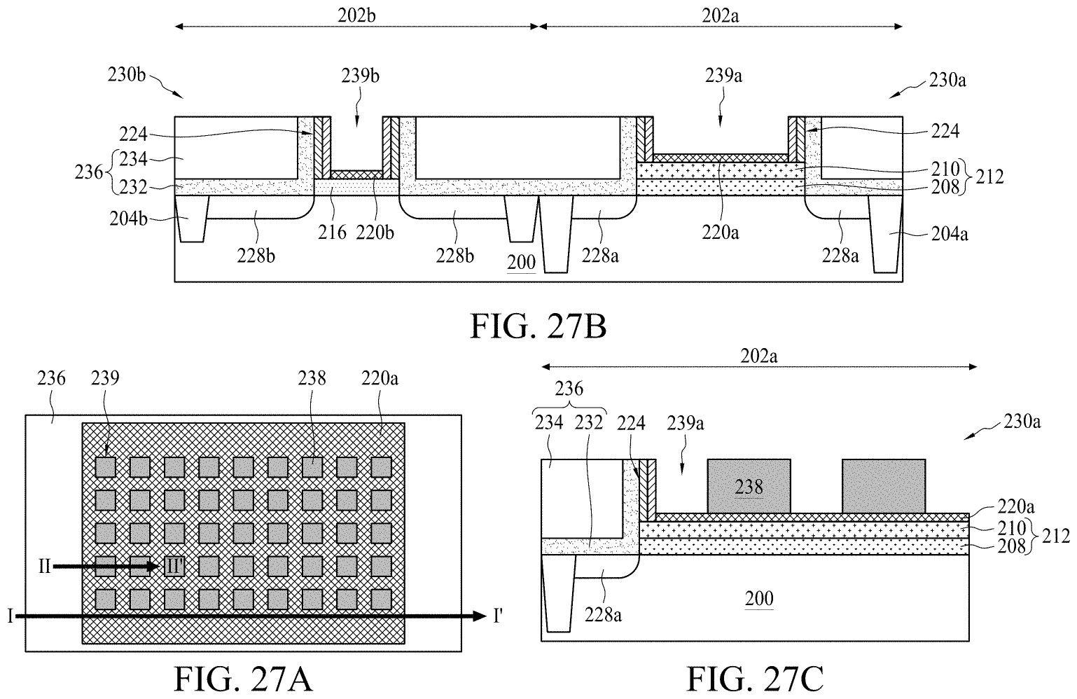

In some embodiments, portions of the sacrificial gate structure 221a remaining in the first region 202a are referred to as a plurality of semiconductor pillars 238 in the first gate trench 239a, as shown in FIGS. 27A and 27C. The semiconductor pillars 238 are separated from each other in the first gate trench 239a. In some embodiments, the semiconductor pillars 238 have a square shape, but the disclosure is not limited thereto. In some embodiments, widths and lengths of the semiconductor pillars 238 are similar to each other, but the disclosure is not limited thereto. In some embodiments, the semiconductor pillars 238 are periodically arranged, as shown in FIG. 27A, but the disclosure is not limited thereto. For example, the semiconductor pillars 238 may be randomly arranged, though not shown. Further, a height of the semiconductor pillars 238 is substantially same as a depth of the first gate trench 239a.

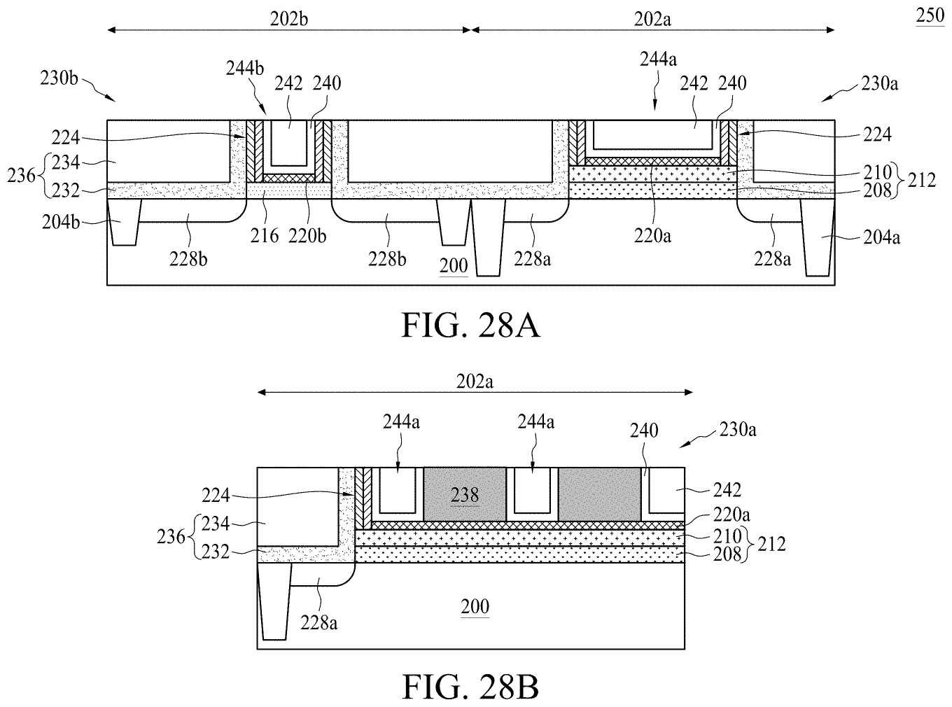

In some embodiments, in operation 16, a first metal gate structure 244a is formed in the first gate trench 239a, and a second metal gate structure 244b is formed in the second gate trench 239b. In some embodiments, the operation 16 includes further operations. Referring to FIGS. 28A and 28B, in some embodiments, a work function metal layer 240 is formed in the first gate trench 239a and the second gate trench 239b. The work function metal layer 240 may include n-type work function metal or p-type work function metal, depending on the product requirements. In some embodiments, the work function metal layer 240 may include a single layer. In some alternative embodiments, the work function metal layer 240 may include a multilayered structure.

A gap-filling metal layer 242 is formed to fill the first gate trench 239a and the second gate trench 239b. A planarization operation such as a CMP may be performed to remove superfluous layers. Accordingly, portions of the work function metal layer 240 and portions of the gap-filling metal layer 242 are removed. Thus, the first metal gate structure 244a is formed in the first region 202a and the second metal gate structure 244b is formed in the second region 202b. Further, the semiconductor pillars 238 are separated from each other by the first metal gate structure 244a, and a top surface of the first metal gate structure 244a and top surfaces of the semiconductor pillars 238 are aligned with each other. As shown in FIG. 28B, the height of the semiconductor pillars 238 is substantially equal to a height of the first metal gate structure 244a.

It should be noted that in some comparative approaches, because the width of the first sacrificial gate structure 221a is greater than the width of the second sacrificial gate structure 221b, a width of the gap-filling metal layer 242 in the first region 202a is greater than a width of t the gap-filling metal layer 242 in the second region 202b. Thus, a dishing issue may be found in the gap-filling metal layer 242 of the first metal gate structure 244a due to a greater polishing area. In contrast with the comparative approaches, the semiconductor pillars 238 of the present disclosure help mitigate the dishing issue by reducing the polishing area of the gap-filling metal layer 242 of the first metal gate structure 244a.

Accordingly, a semiconductor structure 250 is obtained as shown in FIGS. 28A and 28B. The semiconductor structure 250 includes the substrate 200, the HV device 230a disposed over the substrate 200, and the LV device 230b disposed over the substrate 200. The HV device 230a includes the first metal gate structure 244a, the first high-k dielectric layer 220a, the first dielectric layer 212, the first source/drain 228a, and the spacers 224. The LV device 230b includes the second metal gate structure 244b, the second high-k dielectric layer 220b, the second dielectric layer 216, the second source/drain 228b, and the spacers 224. Further, the semiconductor structure 250 includes the plurality of semiconductor pillars 238 disposed in the first metal gate structure 244a.

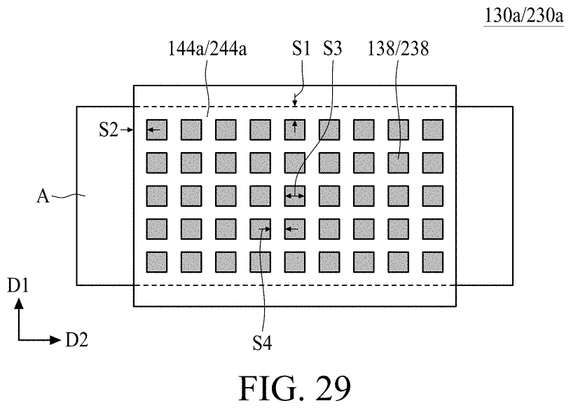

Please refer to FIG. 29, which is a top view of the HV device 130a or 230a. In some embodiments, the first region 102a/202a may be defined by the isolation structures 104a/204a, and the first metal gate structure 144a/244a is disposed in the first region 102a/202a. In some embodiments, a first distance S1 is defined between an edge of the pillar 138/238 and an edge of the first region 102a/202a in a first direction DL, and a second distance S2 is defined between an edge of the pillar 138/238 and an edge of the first metal gate structure 144a/244a in a second direction D2. Further, the first direction D1 and the second direction D2 are perpendicular. In some embodiments, the first distance S1 is equal to or greater than 0.5 micrometer, and the second distance S2 is equal to or greater than 0.5 micrometer. In some embodiments, the first distance S1 and the second distance S2 are equal to each other. In some alternative embodiments, the first distance S1 and the second distance S2 are different. Each of the pillars 138/238 has a width S3. A third distance S4 is defined between two adjacent pillars 138/238. In some embodiments, the third distance S4 may be equal to, less than or greater than the width S3 of the pillars 138/238, depending on different process requirements.

In summary, the present disclosure provides a semiconductor structure and a method for forming a semiconductor structure. The semiconductor structure is formed in an HKMG process for providing multiple-Vt capability. In some embodiments, the method for forming the semiconductor structure includes providing dielectric layers having different thicknesses for providing multiple-Vt capability. For example, a thicker dielectric layer is provided for the HV device, while a thinner dielectric layer is provided for the LV device. Further, the method for forming the semiconductor structure includes providing dielectric pillars or semiconductor pillars in the metal gate structure of an HV device. The semiconductor pillars or dielectric pillars help to mitigate a dishing issue in a planarization in the HKMG process when a dimension of the metal gate structure is equal to or greater than 150 μm², but the disclosure is not limited thereto. Briefly speaking, the method provides dielectric layers having different thicknesses for providing the multiple-Vt capability, and provides the semiconductor pillars or dielectric pillars to mitigate the dishing issue.

Some embodiments of the present disclosure provide a semiconductor structure. The semiconductor structure includes a first device, a second device, and a plurality of pillars. The first device includes a first dielectric layer, a first high-k dielectric layer over the first dielectric layer, and a first metal gate structure. The second device includes a second dielectric layer, a second high-k dielectric layer over the second dielectric layer, and a second metal gate structure. The first dielectric layer has a first thickness, the second dielectric layer has a second thickness, and the second thickness is less than the first thickness. The pillars are disposed in the first metal gate structure. Further, the pillars are separated from each other by the first metal gate structure.

Some embodiments of the present disclosure provide a semiconductor structure. The semiconductor structure includes a substrate having a first region and a second region, a first dielectric layer disposed in the first region, a first high-k dielectric layer over the first dielectric layer in the first region, a first metal gate structure over the first high-k dielectric layer in the first region, a second dielectric layer disposed in the second region, a second high-k dielectric layer over the second dielectric layer in the second region, a second metal gate structure over the second high-k dielectric layer, and a plurality of pillars disposed in the first metal gate structure. The first metal gate structure has a first width, the second metal gate structure has a second width, and the second width is less than the first width. The pillars are separated from each other at least by the first metal gate structure.

Some embodiments of the present disclosure provide a method for forming a semiconductor structure. The method includes following operations. A substrate having a first region and a second region is received. A first dielectric layer is formed in the first region, and a second dielectric layer is formed in the second region. A thickness of the second dielectric layer is less than a thickness of the first dielectric layer. A first sacrificial gate structure is formed in the first region, and a second sacrificial gate structure is formed in the second region. A width of the first sacrificial gate structure is greater than a width of the second sacrificial gate structure. A dielectric structure is formed over the substrate and surrounds the first sacrificial gate structure and the second sacrificial gate structure. The first sacrificial gate structure is removed to form a first gate trench in the first region, and a plurality of pillars are formed in the first gate trench. The second sacrificial gate structure is removed to form a second gate trench in the second region. A first metal gate structure is formed in the first gate trench, and a second metal gate structure is formed in the second gate trench. The first metal gate structure surrounds the pillars.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure comprising:
a first device comprising a first dielectric layer, a first high-k dielectric layer over the first dielectric layer, and a first metal gate structure, wherein the first dielectric layer has a first thickness;
a second device comprising a second dielectric layer, a second high-k dielectric layer over the second dielectric layer, and a second metal gate structure, wherein the second dielectric layer has a second thickness less than the first thickness of the first dielectric layer; and
a plurality of pillars disposed in the first metal gate structure and separated from each other by the first metal gate structure.

2. The semiconductor structure of claim 1, wherein the pillars comprise dielectric pillars, and a height of the dielectric pillars is substantially equal to a sum of a height of the first metal gate structure and the first thickness of the first dielectric layer.

3. The semiconductor structure of claim 1, wherein the pillars comprise semiconductor pillars, and a height of the semiconductor pillars is substantially equal to a height of the first metal gate structure.

4. The semiconductor structure of claim 1, wherein the pillars are randomly or periodically arranged within the first metal gate structure.

5. The semiconductor structure of claim 1, wherein a top surface of the first metal gate structure is substantially aligned with top surfaces of the pillars.

6. The semiconductor structure of claim 1, wherein a width of the first metal gate structure is greater than a width of the second metal gate structure.

7. A semiconductor structure comprising:
a substrate having a first region and a second region;
a first dielectric layer disposed in the first region;
a first high-k dielectric layer over the first dielectric layer in the first region;
a first metal gate structure over the first high-k dielectric layer in the first region and having a first width;
a second dielectric layer disposed in the second region;
a second high-k dielectric layer over the second dielectric layer in the second region;
a second metal gate structure over the second high-k dielectric layer in the second region and having a second width less than the first width; and
a plurality of pillars disposed in the first metal gate structure and separated from each other by at least the first metal gate structure.

8. The semiconductor structure of claim 7, wherein the first dielectric layer has a first thickness, the second dielectric layer has a second thickness, and the first thickness is greater than the second thickness.

9. The semiconductor structure of claim 7, wherein the pillars comprise dielectric pillars, and a height of the dielectric pillars is greater than a height of the first metal gate structure.

10. The semiconductor structure of claim 9, wherein the dielectric pillars are in contact with the substrate.

11. The semiconductor structure of claim 7, wherein the pillars comprise semiconductor pillars, and a height of the semiconductor pillars is equal to a height of the first metal gate structure.

12. The semiconductor structure of claim 11, wherein the semiconductor pillars are in contact with the first high-k dielectric layer.

13. The semiconductor structure of claim 7, wherein the pillars are randomly or periodically arranged within the first metal gate structure.

14. A method for forming a semiconductor structure comprising:
receiving a substrate having a first region and a second region;
forming a first dielectric layer in the first region and a second dielectric layer in the second region, wherein a thickness of the second dielectric layer is less than a thickness of the first dielectric layer;
forming a first sacrificial gate structure in the first region and a second sacrificial gate structure in the second region, wherein a width of the first sacrificial gate structure is greater than a width of the second sacrificial gate structure;
forming a dielectric structure over the substrate and surrounding the first sacrificial gate structure and the second sacrificial structure;
removing the first sacrificial gate structure to form a first gate trench and a plurality of pillars in the first gate trench in the first region, and removing the second sacrificial gate structure to form a second gate trench in the second region; and
forming a first metal gate structure in the first gate trench and a second metal gate structure in the second gate trench, wherein the first metal gate structure surrounds the pillars.

15. The method of claim 14, wherein the forming of the first dielectric layer and the second dielectric layer further comprises:
forming a first mask layer in the second region;
forming the first dielectric layer in the first region;
removing the first mask layer;
forming a second mask layer in the first region; and
forming the second dielectric layer in the second region,
wherein a tilted step is formed at a boundary between the first dielectric layer and the second dielectric layer.

16. The method of claim 15, wherein the forming of the first sacrificial gate structure and the second sacrificial gate structure comprises:
forming a high-k dielectric layer over the first dielectric layer, the second dielectric layer and the tilted step;
forming a sacrificial layer over the high-k dielectric layer;
removing portions of the sacrificial layer and portions of the high-k dielectric layer to form the second sacrificial gate structure;
removing portions of the second dielectric layer exposed through the second sacrificial gate structure;
removing portions of the sacrificial layer and portions of the high-k dielectric layer to form the first sacrificial gate structure;
removing portions of the first dielectric layer exposed through the first sacrificial gate structure; and
forming a plurality of openings separated from each other in the first sacrificial gate structure.

17. The method of claim 16, wherein the forming of the openings further comprises:
forming a plurality of opening simultaneously with the forming of the first sacrificial gate structure; and
deepening the openings simultaneously with the removing of the portions of the first dielectric layer.

18. The method of claim 16, wherein the forming of the openings is performed after the removing of the portions of the first dielectric layer.

19. The method of claim 16, wherein the forming of the dielectric structure further comprises filling the openings to form the pillars.

20. The method of claim 14, wherein the pillars comprise semiconductor pillars.
